(19) United States
(12) Patent Application Publication
(10) Pub. No.: US 2014/0098503 A1
(43) Pub. Date: Apr. 10, 2014

(54) ELECTRONIC DEVICE

(71) Applicants: Mao-Sheng Huang, Taipei City (TW); Cheng-Hung Shih, Taipei City (TW)

(72) Inventors: Mao-Sheng Huang, Taipei City (TW); Cheng-Hung Shih, Taipei City (TW)

(21) Appl. No.: 13/684,174

(22) Filed: Nov. 22, 2012

(30) Foreign Application Priority Data
Oct. 9, 2012 (TW) 101219570

(51) Int. Cl. H05K 9/00; H05K 5/02

(52) U.S. Cl. CPC H05K 9/0067; H05K 5/02
USPC 361/752

(57) ABSTRACT

An electronic device includes a casing, a circuit board, an electronic component and a plurality of conductive elements. The circuit board is disposed in the casing. The electronic component is disposed on the circuit board and has a shielding surface and an electronic components body, in which the shielding surface and the casing together form a common casing surface, and there is a slit between the shielding surface and the casing. The conductive elements are disposed on the circuit board and grounded, in which the center position of each of the conductive elements and the edge of the shielding surface overlap each other, and the distance between the edge of the shielding surface and the conductive element is less than the distance between the edge of the shielding surface and the electronic component main body to evacuate static electricity around the electronic component.

### CROSS-REFERENCE TO RELATED APPLICATION

This application claims the priority benefit of Taiwan application serial no. 101219570, filed on Oct. 9, 2012. The entirety of the above-mentioned patent application is hereby incorporated by reference herein and made a part of this specification.

### BACKGROUND OF THE INVENTION

1. Field of the Invention

The invention generally relates to an electronic device, and more particularly, to an electronic device with a slit on the outward appearance thereof.

2. Description of Related Art

With the development of electronic technology, notebook computers, tablet computers, smart phones and other various electronic products have become more popular in the mass market to be indispensable portable tools of many users.

Many electronic devices are equipped with keys for user to input. Because the human body carries more or less static electricity, so when a user manipulates keys, static electricity on the body of the user may be delivered via a finger and through the slits between the keys and electronic device to the circuit board inside the electronic device, which results in the phenomenon of electrostatic discharge (ESD) and leads to short circuit or damage. In some conventional designs, plastic spacers, metal mesh or metal foil or other members are disposed at the keys or the electronic device casing in order to prevent electric charges from entering the circuit board or guide electric charges to ground for releasing. However, such design will increase the design and manufacturing costs and the complexity of the structure, and will affect the touch feeling of the keys.

### SUMMARY OF THE INVENTION

Accordingly, the invention is directed to an electronic device, which achieves the effect of electrostatic protection by a simpler design.

The invention provides an electronic device, which includes a casing, a circuit board, an electronic component and a plurality of conductive elements. The circuit board is disposed in the casing. The electronic component is disposed on the circuit board and has a shielding surface and an electronic components body, in which the shielding surface and the casing together form a common casing surface, and there is a slit between the shielding surface and the casing. The conductive elements are disposed on the circuit board and grounded, in which the center position of each of the conductive elements and the edge of the shielding surface overlap each other, and the distance between the edge of the shielding surface and the conductive element is less than the distance between the edge of the shielding surface and the electronic component main body to evacuate static electricity around the electronic component.

In an embodiment of the invention, the electronic component is a key or a light emitting diode (LED) light sensor.

In an embodiment of the invention, the conductive element is a solder ball.

In an embodiment of the invention, the casing has an inner surface, the inner surface faces the circuit board and the shielding surface extends to a position between the inner surface and the circuit board.

In an embodiment of the invention, the length of the orthogonal projection of the shielding surface on the inner surface is greater than 2 mm.

In an embodiment of the invention, the conductive elements surround the electronic component main body.

Based on the description above, in the invention, the conductive elements are disposed on the circuit board, the center position of each of the conductive elements and the edge of the shielding surface overlap each other, and the distance between the edge of the shielding surface and the conductive element is less than the distance between the edge of the shielding surface and the electronic component main body. In this way, when the finger of a user touches or approaches the slit between the shielding surface and the casing, and static electricity carried on the body of the user enters the electronic device via the slit, the static electricity is guided by the conductive elements adjacent to the slits to the ground for releasing, which can avoid the ESD phenomena to cause the circuit board short circuit or damage. Since the conductive elements are disposed on the circuit board, not at the casing or the keys of the electronic device, the above-mentioned design would not affect the touch feeling of manipulating the keys and save the design and manufacturing costs.

In order to make the features and advantages of the present invention more comprehensible, the present invention is further described in detail in the following with reference to the embodiments and the accompanying drawings.

### BRIEF DESCRIPTION OF THE DRAWINGS

FIG. 1 is a partial cross-sectional diagram of an electronic device according to an embodiment of the invention.

FIG. 2 is a top-view diagram of partial parts of the electronic device in FIG. 1.

FIG. 3 is a partial cross-sectional diagram of an electronic device according to another embodiment of the invention.

### DESCRIPTION OF THE EMBODIMENTS

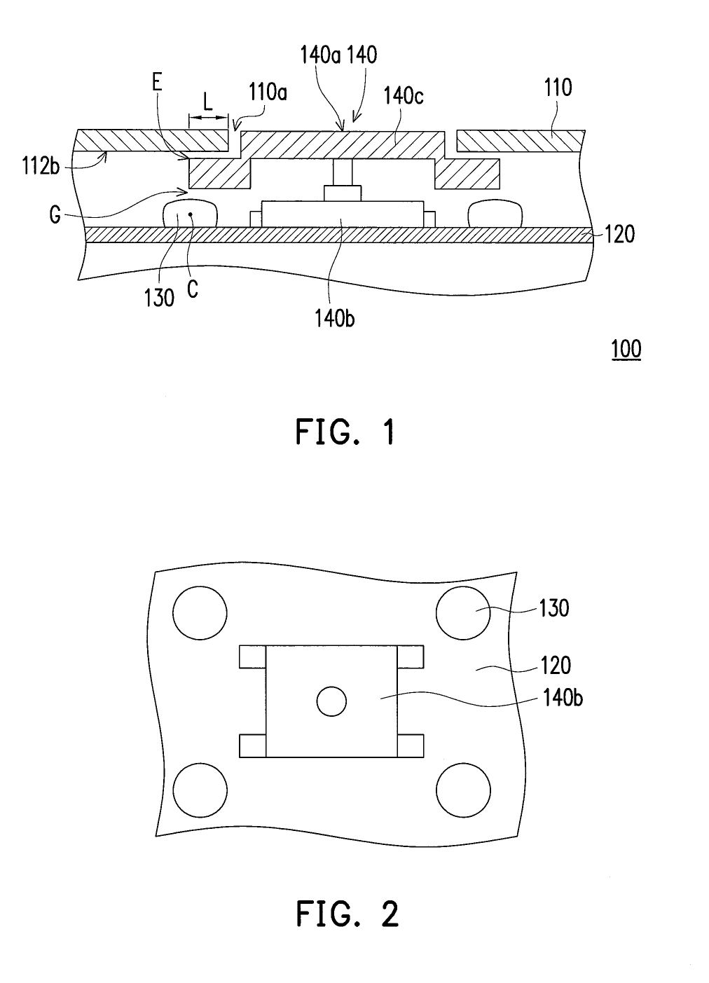

FIG. 1 is a partial cross-sectional diagram of an electronic device according to an embodiment of the invention. An electronic device 100 in the embodiment includes a casing 110, a circuit board 120, an electronic component 140 and a plurality of conductive elements 130. The circuit board 120 is disposed in the casing 110. The electronic component 140 is disposed on the circuit board 120 and has a shielding surface 140a and an electronic component main body 140b. The shielding surface 140a and the casing 110 together form a common casing surface, and there is a slit 110a between the shielding surface 140a and the casing 110. Each of the conductive elements 130 is, for example, a solder ball and disposed on the circuit board 120 and grounded. The center position C of each of the conductive elements 130 and the edge E of the shielding surface 140a overlap each other, and the distance between the edge E of the shielding surface 140a and the conductive element 130 is less than the distance between the edge E of the shielding surface 140a and the electronic component main body 140b so as to evacuate static electricity around the electronic component 140.

The electronic device 100 in the embodiment is, for example, an electronic product with keys, for example, notebook computer, and the electronic component 140 is, for example, the keys of the notebook computer. In other embodiments, the electronic component 140 can be other types of components, for example, LED light sensor disposed at the video lens of a notebook computer, which the invention is not limited to.

With the above-mentioned layout, the center position C of each of the conductive elements 130 and the edge E of the shielding surface 140a of the electronic component 140 overlap each other, and the distance between the edge E of the shielding surface 140a and the conductive element 130 is less than the distance between the edge E of the shielding surface 140a and the electronic component main body 140b. In this way, when the finger of a user touches or approaches the slit 110a between the shielding surface 140a and the casing 110 (for example, as pressing the keys), and static electricity carried on the body of the user enters the electronic device 100 via the slits 110a, the static electricity is guided by the conductive elements 130 close to the slits 110a to the ground for releasing, which can avoid the ESD phenomena to cause the circuit board 120 short circuit or damage. Since the conductive elements 130 are disposed on the circuit board 120, not at the casing 110 or the keys (the electronic component 140), the above-mentioned design would not affect the touch feeling of manipulating the keys and not increase the complexity of the structure, and will save the design and manufacturing costs.

In more details, in the embodiment, the casing 110 has an inner surface 112b, the inner surface 112b faces the circuit board 120, and the shielding surface 140a of the electronic device 100 extends to a position between the inner surface 112b and the circuit board 120. When the finger of the user touches or approaches the slit 110a between the shielding surface 140a and the casing 110, static electricity carried on the body of the user can arrive at the edge E of the shielding surface 140a via the slit 110a between the shielding surface 140a and the inner surface 112b and enter the electronic device 100. As shown by

FIG. 1, the center position C of each of the conductive elements 130 is aligned with the edge E of the shielding surface 140a and has a shorter distance from the edge E, so that the static electricity is able to enter the electronic device 100 via the slits 110a and then easy to be guided by the conductive elements 130 to the ground to be released without damaging the electronic component main body 140b on the circuit board 120.

In the embodiment, the length L of the orthogonal projection of the shielding surface 140a of the electronic component 140 on the inner surface 112b of the casing 110 is, for example, greater than 2 mm, so that static electricity entering the electronic device 100 via the slits 110a is more far away from the electronic component main body 140b and closer to the conductive elements 130. In other embodiments, the orthogonal projection of the shielding surface 140a on the inner surface 112b of the casing 110 can have other appropriate lengths, which the invention is not limited to. In addition, in the embodiment, there is an interval G between the conductive elements 130 and the electronic component 140 to allow the keycaps 140c of the electronic component 140 has a downward space as pressing down the electronic component 140 and facilitate operating the electronic component 140 by the user. In other embodiments, the height of the conductive elements 130 can be changed according to the design requirement so that an appropriate interval is kept between the conductive elements 130 and the electronic component 140.

FIG. 2 is a top-view diagram of partial parts of the electronic device in FIG. 1. Referring to FIG. 2, in the embodiment, the number of the conductive elements 130 is, for example, four, and the conductive elements 130 surround the electronic component main body 140b to effectively prevent the electronic component main body 140b from damaging by static electricity. In other embodiments, the conductive elements 130 can have other quantity and appropriate disposing positions, which the invention is not limited to.

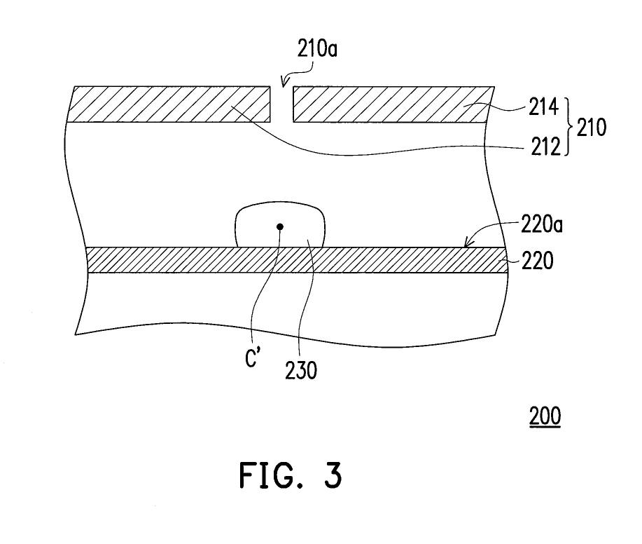

FIG. 3 is a partial cross-sectional diagram of an electronic device according to another embodiment of the invention. Referring to FIG. 3, an electronic device 200 of the embodiment includes a casing 210, a circuit board 220 and at least one conductive element 230. The casing 210 includes a first housing 212 and a second housing 214, and there is a slit 210a formed between the first housing 212 and the second housing 214. The circuit board 220 is disposed in the casing 210 and has an upper surface 220a. The upper surface 220a faces the slit 210a of the casing 210. The conductive element 230 is, for example, a solder ball, and the conductive element 230 is fixed on the upper surface 220a of the circuit board 220 and grounded. In the embodiment, the center position C′ of the conductive element 230 is, for example, aligned with the slit 210a of the casing 210 to make the distance between the conductive element 230 and the slit 210a smaller. Thus, after static electricity enters the electronic device 200 via the slit 210a, the static electricity is easier to be guided by the conductive element 230 to the ground to be released without damaging the circuit board 220

In summary, in the invention, the conductive elements are disposed on the circuit board, the center position of each of the conductive elements and the edge of the shielding surface overlap each other, and the distance between the edge of the shielding surface and the conductive element is less than the distance between the edge of the shielding surface and the electronic component main body. In this way, when the finger of a user touches or approaches the slit between the shielding surface and the casing, and static electricity carried on the body of the user enters the electronic device via the slit, the static electricity is guided by the conductive elements adjacent to the slits to the ground for releasing, which can avoid the ESD phenomena to cause the circuit board short circuit or damage. Since the conductive elements are disposed on the circuit board, not at the casing or the keys of the electronic device, the above-mentioned design would not affect the touch feeling of manipulating the keys, not increase the structure complexity of the casing or keys, and save the design and manufacturing costs.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. An electronic device , comprising:
a casing;
a circuit board, disposed in the casing;
an electronic component, disposed on the circuit board and having a shielding surface and an electronic component main body, wherein the shielding surface and the casing together form a common casing surface, and there is a slit between the shielding surface and the casing; and
a plurality of conductive elements, disposed on the circuit board and grounded, wherein a center position of each of the conductive elements and an edge of the shielding surface overlap each other, and a distance between the edge of the shielding surface and the conductive element is less than a distance between the edge of the shielding surface and the electronic component main body to evacuate static electricity around the electronic component.

2. The electronic device as claimed in claim 1, wherein the electronic component is a key or a light emitting diode light sensor.

3. The electronic device as claimed in claim 1, wherein the conductive element is a solder ball.

4. The electronic device as claimed in claim 1, wherein the casing has an inner surface, the inner surface faces the circuit board and the shielding surface extends to a position between the inner surface and the circuit board.

5. The electronic device as claimed in claim 4, wherein a length of a orthogonal projection of the shielding surface on the inner surface is greater than 2 mm.

6. The electronic device as claimed in claim 1, wherein the conductive elements surround the electronic component main body.
